(19) United States
(12) Patent Application Publication
(10) Pub. No.: US 2026/0194556 A1
(43) Pub. Date: Jul. 9, 2026

(54) ALIGNMENT DEVICE FOR SHIELDING EFFECTIVENESS MEASURING INSTRUMENT

(71) Applicant: Korea Testing Laboratory (KTL), Jinju-si (KR)

(72) Inventors: Tae Seuong SONG, Suwon-si (KR); Sang Wook YOON, Ansan-si (KR); Han Hee LEE, Seoul (KR); Hong Je JANG, Gwangju-si (KR)

(21) Appl. No.: 19/063,354

(22) Filed: Feb. 26, 2025

(30) Foreign Application Priority Data
Jan. 6, 2025 (KR) 10-2025-0001482

(51) Int. Cl. G01R 1/04; G01R 29/08; H05K 9/00

(52) U.S. Cl. CPC G01R 1/04; G01R 29/0835; H05K 9/0069

(57) ABSTRACT

Proposed is an alignment device including a first insert configured to be inserted into a first alignment hole, instead of a screw that penetrates a sample and is screwed into the first alignment hole of a first measuring instrument and a second alignment hole of a second measuring instrument, when the first measuring instrument and the second measuring instrument aligned with each other with the sample in between are provided, a second insert configured to be inserted into the second alignment hole, instead of the screw, a first adjuster connected to a second side of the first insert when a first side of the first insert is inserted into the first alignment hole, and a connector extending along a path spaced apart from the first measuring instrument and the second measuring instrument.

### CROSS REFERENCE TO RELATED APPLICATION

The present application claims priority to Korean Patent Application No. 10-2025-0001482, filed January 06, 2025, the entire contents of which is incorporated herein for all purposes by this reference.

### BACKGROUND

### Technical Field

The present disclosure relates to an alignment device for shielding effectiveness measuring instruments that can be used in testing such as ASTM D4935.

### Description of the Related Art

There are various methods for measuring the electromagnetic shielding effectiveness of materials (samples).

For example, test methods for measuring the shielding effectiveness specified by the American Society for Testing and Materials (ASTM) includes the D4935 standard, which involves placing a sample in close contact between two barrel-shaped measuring instruments disposed facing each other.

The ASTM D4935 method uses a flanged, coaxial transmission line measuring instrument. Two measuring instruments are placed by aligning alignment holes formed in each measuring instrument, and a sample with holes drilled in a position matching the corresponding the alignment holes is placed between the two measuring instruments.

To maintain alignment between the two measuring instruments and the sample, a screw installed through the alignment holes and the holes of the sample is used. In this case, the screw may be made of a non-metallic material that does not affect the shielding effectiveness.

One of the disadvantages of the ASTM D4935 method is that it is practically difficult to drill holes in the exact locations corresponding to alignment holes in a sample. Damage to non-metallic screws that break easily is another drawback. Due to these problems, the ASTM D4935 method requires a lot of time for measurement.

### SUMMARY

Accordingly, the present disclosure has been made keeping in mind the above problems occurring in the related art, and the present disclosure is intended to provide an alignment device for shielding effectiveness measuring instruments, which does not require drilling a hole in a sample that match an alignment hole of a measuring instrument.

In order to achieve the above objective, according to an aspect of the present disclosure, there is provided an alignment device including: an insert unit configured to be inserted, instead of a screw, into an alignment hole of a measuring instrument that is conventionally aligned using the screw; and a support unit configured to support the insert unit on both sides of the alignment hole.

In order to achieve the above objective, according to an aspect of the present disclosure, there is provided an alignment device including: a first insert configured to be inserted into a first alignment hole, instead of a screw that penetrates a sample and is screwed into the first alignment hole of a first measuring instrument and a second alignment hole of a second measuring instrument, when the first measuring instrument and the second measuring instrument aligned with each other with the sample in between are provided; a second insert configured to be inserted into the second alignment hole, instead of the screw; a first adjuster connected to a second side of the first insert when a first side of the first insert is inserted into the first alignment hole; and a connector extending along a path spaced apart from the first measuring instrument and the second measuring instrument.

A first end of the connector may be connected to the first adjuster.

A second end of the connector may be connected to the second insert.

The first adjuster may move the first insert toward the first alignment hole or move the first insert away from the first alignment hole.

When the first alignment hole is made on a first surface of the first measuring instrument, a first plate may be provided in face-to-face contact with the first surface.

A first guide may be provided that protrudes from the first plate toward the first alignment hole and is inserted into the first alignment hole.

The first plate and the first guide may be made of a non-metallic material.

When the first guide is provided on a first side of the first plate, the first adjuster may be connected to a second side of the first plate.

When the second alignment hole is made on a second surface of the second measuring instrument, a second plate may be provided in face-to-face contact with the second surface.

A second guide may be provided that protrudes from the second plate toward the second alignment hole and is inserted into the second alignment hole.

The second plate and the second guide may be made of a non-metallic material.

When the second guide is provided on a first side of the second plate, the second end of the connector may be connected to a second side of the second plate.

The first guide may protrude from the first plate shorter than a depth of the first alignment hole.

An end of the first guide inserted into the first alignment hole may not be able to escape the first alignment hole and may be located within the first alignment hole.

The second guide may protrude from the second plate shorter than a depth of the second alignment hole.

An end of the second guide inserted into the second alignment hole may not be able to escape the second alignment hole and may be located within the second alignment hole.

A first support may be provided to face the first surface at a position spaced apart from the first surface.

A second support may be provided to face the second surface with the second plate interposed therebetween.

A third support may be provided to be spaced apart from the first measuring instrument and the second measuring instrument and to connect the first support and the second support.

A first through hole may be made in the first support through which the first adjuster is installed.

The first adjuster may be screw-connected to the first through hole.

When the first adjuster rotates in a forward direction, the first adjuster may move toward the first surface, bringing the first plate into close contact with the first surface and pushing the first guide into the first alignment hole.

When the first adjuster rotates in a reverse direction, the first adjuster may move away from the first surface, separating the first plate from the first surface and separating the first guide from the first alignment hole.

A second through hole may be formed in the second support through which the second adjuster is installed.

The second adjuster may be screw-connected to the second through hole.

When the second adjuster rotates in a forward direction, the second adjuster may move toward the second surface, bringing the second plate into close contact with the second surface and pushing the second guide into the second alignment hole.

When the second adjuster rotates in a reverse direction, the second adjuster may move away from the second surface, separating the second plate from the second surface and separating the second guide from the second alignment hole.

The first support may extend on both sides along the first surface with the first alignment hole located in the center in a plan view.

The second support may extend on both sides along the second surface with the second alignment hole located in the center in a plan view.

A first support may be provided to face a first surface at a position spaced apart from the first surface of the first measuring instrument in which the first alignment hole is made.

A second support may be provided to face a second surface of the second measuring instrument in which the second alignment hole is made, with the second plate interposed therebetween.

A third support may be provided to be spaced apart from the first measuring instrument and the second measuring instrument and to connect the first support and the second support.

The third support may be expanded and contracted by the first adjuster.

A first flange having the first alignment hole may be provided at an end of the first measuring instrument, whereas a second flange having the second alignment hole may be provided at an end of the second measuring instrument, and when the first flange and the second flange come into close contact with the sample in between, the connector may be provided in a “U” shape in cross section with a groove formed in a center thereof.

The connector may be arranged such that the first flange and the second flange, which are in close contact with each other, are inserted into the groove formed in the center of the connector.

The connector may be arranged to be spaced apart from the first measuring instrument and the second measuring instrument so as not to contact either the first flange or the second flange.

The center of the connector may face side surfaces of the first flange and the second flange.

The first end of the connector may extend toward an entrance of the first alignment hole exposed on the first surface of the first flange.

A first through hole through which the first adjuster is installed by screwing may be formed at the first end of the connector.

The second end of the connector may extend toward an entrance of the second alignment hole exposed on the second surface of the second flange.

The second insert may be directly connected to the second end of the connector or may be indirectly connected to the second end of the connector through the second adjuster.

The first insert and the second insert may be made of a non-metallic material.

The first adjuster and the connector may be made of a metallic material.

According to the present disclosure, an alignment device may be provided to align alignment holes of the two measuring instruments instead of a screw passing through two alignment holes facing each other.

The alignment device may be configured to extend along the external space of the instrument instead of using a path through two alignment holes.

For example, the alignment device may be formed to surround two alignment holes arranged overlapping each other from the outside. Additionally, the alignment device may be provided with a first insert fitted into a first alignment hole and a second insert fitted into a second alignment hole. The inserts may be connected by the alignment device. If only the two inserts that fit into the alignment holes are made of non-metallic material, a connector connecting the two inserts may not affect measurement results such as shielding effectiveness even if the connector is made of a high-strength material, for example, a metallic material.

As a result, according to the alignment device of the present disclosure, there is no need to use a screw made of non-metallic material. In addition, there is no need to drill a screw hole in a sample through which the corresponding screw passes.

Since the time for drilling screw holes in a sample is saved, according to the present disclosure, an environment can be provided in which various samples can be quickly evaluated or measured.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic view showing a state in which two measuring instruments are aligned by an alignment device according to an embodiment of the present disclosure;

FIG. 2 is a schematic view showing the aligned state of the measuring instruments by the alignment device according to an embodiment of the present disclosure is released;

FIG. 3 is a schematic view showing an alignment device of a comparative example using a screw;

FIG. 4 is a schematic view showing a sample applied to the alignment device of a comparative example using the screw;

FIG. 5 is a schematic view showing an alignment device and measuring instruments according to another embodiment of the present disclosure; and

FIG. 6 is a schematic view showing the alignment device according to another embodiment of the present disclosure.

### DETAILED DESCRIPTION

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein. In order to clearly describe the present disclosure, parts irrelevant to the description are omitted in the drawings, and same reference numerals are assigned to the same or similar components throughout the specification.

In this specification, redundant descriptions of the same components are omitted.

In addition, in this specification, when a component is said to be “connected (or coupled)” to another component, this includes not only the case of being “directly connected (or coupled)” but also “indirectly connected (or coupled)” with another component in between. On the other hand, when a component is said to be “directly connected (or coupled)” to another component, it should be understood that there are no other components in between.

The terms used in this specification are only used to describe specific embodiments, and are not intended to limit the present disclosure.

The singular expression may include a plural expression unless the context clearly indicates otherwise.

In addition, it should be understood that in the present disclosure, terms such as “comprise” or “have” are intended to designate that a feature, number, step, operation, component, part, or combination thereof described in the specification exists, and do not preclude the possibility of addition or existence of one or more other features or numbers, steps, operations, components, parts, or combinations thereof.

As used herein, the term “and/or” includes a combination of a plurality of listed items or any of a plurality of listed items. As used herein, “A or B” may include “A”, “B”, or “both A and B”.

In this specification, detailed descriptions of well-known functions and configurations that may obscure the gist of the present disclosure will be omitted.

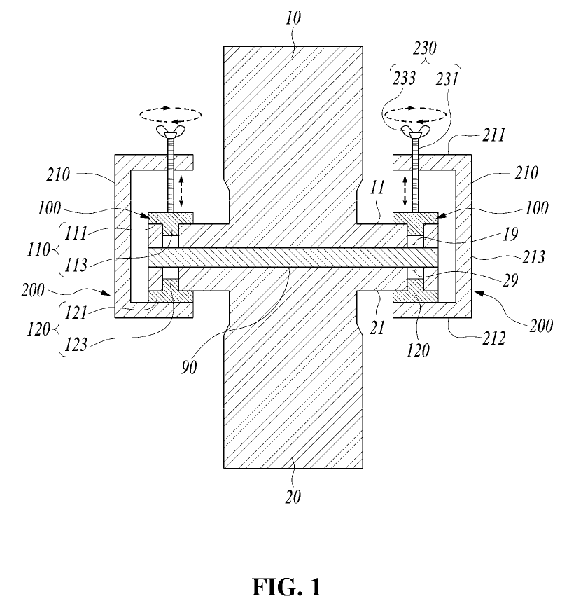

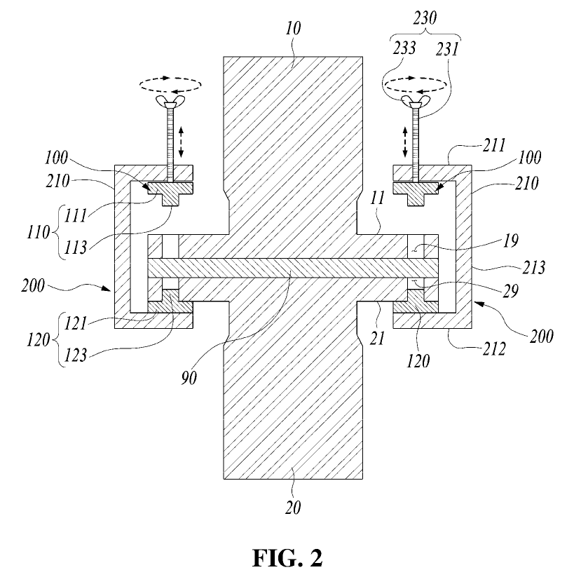

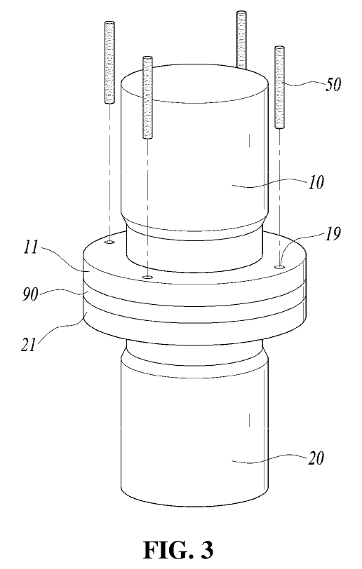

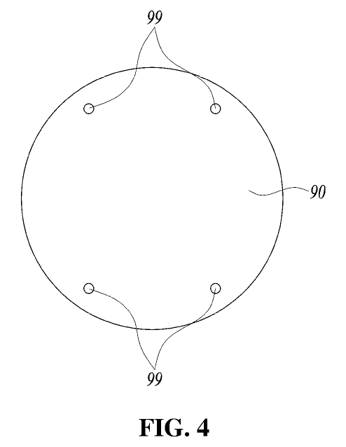

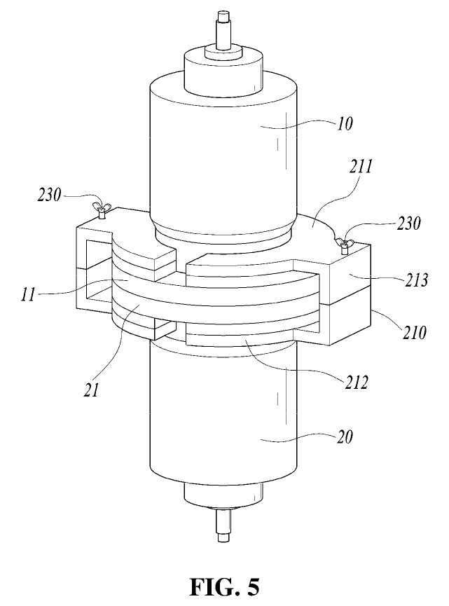

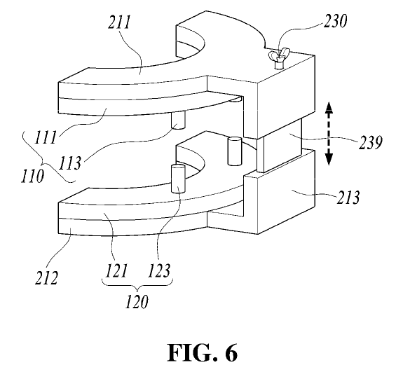

FIG. 1 is a schematic view showing a state in which two measuring instruments are aligned by an alignment device according to an embodiment of the present disclosure; FIG. 2 is a schematic view showing the aligned state of the measuring instruments by the alignment device according to an embodiment of the present disclosure is released; FIG. 3 is a schematic view showing an alignment device of a comparative example using a screw 50; FIG. 4 is a schematic view showing a sample 90 applied to the alignment device of a comparative example using the screw 50; FIG. 5 is a schematic view showing an alignment device and measuring instruments according to another embodiment of the present disclosure; and FIG. 6 is a schematic view showing the alignment device according to another embodiment of the present disclosure.

The alignment device shown in the drawing may include an insert unit 100 and a support unit 200.

The insert unit 100 may be inserted, instead of the screw 50, into an alignment hole of a measuring instrument that is conventionally aligned using the screw 50.

The support unit 200 supports the insert unit 100 on opposite sides(both sides) of the alignment hole.

For example, a first measuring instrument 10 and a second measuring instrument 20, each of which has a flange at an end thereof, may be arranged to face each other. At this time, the state in which the first measuring instrument 10 and the second measuring instrument 20 are arranged so that a first alignment hole 19 and a second alignment hole 29 formed on the flanges of each measuring instrument match each other will be referred to as an aligned state.

The screw 50 installed through the first alignment hole 19 and the second alignment hole 29 may be provided to maintain the aligned state. However, with regard to the screw 50 passing through the first alignment hole 19 and the second alignment hole 29, the sample 90 disposed between the first alignment hole 19 and the second alignment hole 29 also needs to have a screw hole 99 through which the screw 50 can pass. Accurately forming the screw hole 99 in the sample 90 before being placed between two measuring instruments may be a task that requires considerable precision. Thus, it may take a lot of time to make the screw hole 99 in the measuring instrument. Moreover, it is difficult to use the sample 90 with the screw hole 99 for other purposes.

In addition, the screw 50 passing through the first alignment hole 19, the second alignment hole 29, and the screw hole 99 comes into contact with all of the first measuring instrument 10, the second measuring instrument 20, and the sample 90. Thus, the screw 50 needs to be made of a non-metallic material that does not affect the measurement results of the electromagnetic shielding effectiveness.

The problem with the screw 50 made of non-metallic material is that the screw 50 breaks or bends easily. For this reason, it is necessary to carefully place the first measuring instrument 10 and the second measuring instrument 20 to avoid damaging the screw 50, a process that may take a lot of effort and time.

In short, the alignment method using the screw 50, recommended by ASTM, is problematic in that the measurement process takes a lot of time and it is difficult to recycle the sample 90.

The insert unit 100 may be inserted into the first alignment hole 19 through the entrance of the first alignment hole 19 in a state where the two alignment holes overlap. At this time, the insertion depth may be set to a level where the insert unit 100 does not go out of the first alignment hole 19.

The insert unit 100 may also be inserted into the second alignment hole 29 through the entrance of the second alignment hole 29. At this time, the insertion depth may be set to a level where the insert unit 100 does not go out of the second alignment hole 29.

In addition, the insert unit 100 may be connected to the support unit 200 extending along a position spaced apart from the side of the flange of the first measuring instrument 10 and spaced apart from the side of the flange of the second measuring instrument 20.

In this state, when the insert unit 100 inserted into the first alignment hole 19 and the insert unit 100 inserted into the second alignment hole 29 are pressed in a direction toward each other, the aligned state of the first measuring instrument 10 and the second measuring instrument 20 may be maintained.

Additionally, if the insert unit 100 is made of a non-metallic material, the support unit 200 may be made of a high-strength metallic material.

According to this embodiment, since members such as screws passing between the first measurement hole and the second measurement hole are excluded, there is no need to make the screw hole 99 in the sample 90.

The insert unit 100 and the support unit 200 will be described in detail.

The insert unit 100 may include a first insert 110 and a second insert 120.

The support unit 200 may include a first adjuster 230 and a connector 210. In some cases, the support unit 200 may further include a second adjuster.

When the first measuring instrument 10 and the second measuring instrument 20, which are aligned with each other with the sample 90 in between, are provided, the first insert 110 may be inserted into the first alignment hole 19 instead of a screw that penetrates the sample 90 and is screwed into the first alignment hole 19 of the first measuring instrument 10 and the second alignment hole 29 of the second measuring instrument 20.

The second insert 120 may be inserted into the second alignment hole 29 instead of the corresponding screw.

The first adjuster 230 may be connected to the other side of the first insert 110 when one side of the first insert 110 is inserted into the first alignment hole 19.

The connector 210 may extend along a path spaced apart from the first measuring instrument 10 and the second measuring instrument 20.

One end of the connector 210 is connected to the first adjuster 230 while the other end of the connector 210 is connected to the second insert 120.

The first adjuster 230 may move the first insert 110 toward the first alignment hole 19 or move the first insert 110 away from the first alignment hole 19.

The first insert 110 may include a first plate 111 and a first guide 113.

When the first alignment hole 19 is formed on a first surface of the first measuring instrument 10, the first plate 111 may be in face-to-face contact with the first surface.

The first guide 113 protrudes from the first plate 111 toward the first alignment hole 19 and may be inserted into the first alignment hole 19.

The first plate 111 and the first guide 113 may be made of a non-metallic material.

When the first guide 113 is formed on one surface of the first plate 111, the first adjuster 230 may be connected to the other surface of the first plate 111. The first adjuster 230 may be connected to one end of the connector 210.

The second insert 120 may include a second plate 121 and a second guide 123.

When the second alignment hole 29 is formed on a second surface of the second measuring instrument 20, the second plate 121 may be in face-to-face contact with the second surface.

The second guide 123 protrudes from the second plate 121 toward second alignment hole 29 and may be inserted into the second alignment hole 29.

The second plate 121 and the second guide 123 may be made of a non-metallic material.

When the second guide 123 is formed on one surface of the second plate 121, the other end of the connector 210 may be connected to the other surface of the second plate 121.

The first guide 113 may protrude from the first plate 111 shorter than the depth of the first alignment hole 19.

Because of this, the first guide 113 is not able to reach the sample 90 disposed between the first alignment hole 19 and the second alignment hole 29. In other words, the end of the first guide 113 inserted into the first alignment hole 19 is not able to escape the first alignment hole 19 and may be located within the first alignment hole 19.

The second guide 123 may protrude from the second plate 121 shorter than the depth of the second alignment hole 29.

Because of this, the end of the second guide 123 inserted into the second alignment hole 29 is not able to escape the second alignment hole 29 and may be located within the second alignment hole 29.

As a result, the sample 90 disposed between the first alignment hole 19 and the second alignment hole 29 is spaced apart from the first guide 113 and the second guide 123 inserted into respective insert. According to this, there is no need to form a hole through which the first guide 113 or the second guide 123 passes in the sample 90.

The connector 210 may include a first support 211, a second support 212, and a third support 213. The first support 211, the second support 212, and the third support 213 may be made of a hard metallic material.

The first support 211 may be provided to face the first surface at a position spaced apart from the first surface of the first measuring instrument 10 where the first alignment hole 19 is formed.

The second support 212 may be provided to face the second surface of the second measuring instrument 20 in which the second alignment hole 29 is formed, with the second plate 121 interposed therebetween. The second support 212 may be disposed in a position spaced apart from the second surface.

The third support 213 may be provided that is spaced apart from the first measuring instrument 10 and the second measuring instrument 20 and connects the first support 211 and the second support 212.

For example, when the first support 211 extends parallel to the first surface and the second support 212 extends parallel to the second surface, the third support 213 may extend at an angle to the first and second surfaces and connect the first support 211 and the second support 212.

A first through hole through which the first adjuster 230 is installed may be formed in the first support 211.

The first adjuster 230 may be connected to the first through hole by screwing. To this end, the first adjuster 230 may include a rod-shaped body 231 having threads on the outer peripheral surface thereof and screwed to the first through hole, and a handle 233 provided at the end of the body 231. The handle 233 may be formed so that a user can hold the handle 233 with his or her hand and turn the body 231.

When the first adjuster 230 rotates in the forward direction, the first adjuster 230 moves toward the first surface, bringing the first plate 111 into close contact with the first surface and pushing the first guide 113 into the first alignment hole 19.

When the first adjuster 230 rotates in the reverse direction, the first adjuster 230 moves away from the first surface, separating the first plate 111 from the first surface and separating the first guide 113 from the first alignment hole 19.

When the first guide 113 is sufficiently moved away from the first alignment hole 19 due to reverse rotation of the first adjuster 230, sufficient space is secured to remove the first guide 113 from the first alignment hole 19 and the second guide 123 from the second alignment hole 29. In this state, the user may remove the alignment device from the measuring instrument. Alternatively, the reverse process allows the user to fit the alignment device to the measuring instrument.

When a second adjuster is additionally provided, the following embodiment is possible.

A second through hole through which the second adjuster is installed may be formed in the second support 212.

The second adjuster may be screwed to the second through hole.

When the second adjuster rotates in the forward direction, the second adjuster moves toward the second surface, bringing the second plate 121 into close contact with the second surface and pushing the second guide 123 into the second alignment hole 29.

When the second adjuster rotates in the reverse direction, the second adjuster moves away from the second surface, separating the second plate 121 from the second surface and separating the second guide 123 from the second alignment hole 29.

The first support 211 may extend on opposite sides from the first alignment hole 19 along the first surface in a plan view over the first alignment hole 19. For example, assuming that the first surface is circular, the first support 211 may extend in an arc shape as shown in FIGS. 5 and 6.

The second support 212 may extend on opposite sides from the second alignment hole 29 along the second surface in a plan view over the second alignment hole 29. For example, assuming that the second surface is circular, the second support 212 may extend in an arc shape as shown in FIGS. 5 and 6.

Meanwhile, as shown in FIG. 6, the third support 213 may be formed to be flexible.

The third support 213 may be expanded and contracted by the first adjuster 230.

For example, the third support 213 may be divided into two members movably connected to each other. One member may be provided with an elastic part 239 extending toward the other member, while the other member may have an insertion space into which the elastic part 239 is inserted.

The first adjuster 230 may be screwed to the third support 213 to insert the elastic part 239 into the insertion space or to pull the elastic part 239 from the insertion space, depending on the direction of rotation. At this time, the first adjuster 230 may be connected to the insert via the first support 211 connected to the third support 213.

An example of a state in which a flange is formed in each measuring instrument is as follows.

A first flange 11 having the first alignment hole 19 may be formed at the end of the first measuring instrument 10, and a second flange 21 having the second alignment hole 29 may be formed at the end of the second measuring instrument 20. In addition, the first flange 11 and the second flange 21 may be in close contact with the sample 90 in between.

At this time, the connector 210 may be provided in a “U” shape in cross section with a groove formed in the center.

The connector 210 may be arranged such that the first flange 11 and the second flange 21, which are in close contact with each other, are inserted into the groove formed in the center of the connector 210.

The connector 210 may be arranged to be spaced apart from the first measuring instrument 10 and the second measuring instrument 20 so as not to contact either the first flange 11 or the second flange 21.

The center of the connector 210 may face the side surfaces of the first flange 11 and the second flange 21.

One end of the connector 210 may extend toward the entrance of the first alignment hole 19 exposed on the first surface of the first flange 11.

A first through hole through which the first adjuster 230 is installed by screwing may be formed at one end of the connector 210.

The other end of the connector 210 may extend toward the entrance of the second alignment hole 29 exposed on the second surface of the second flange 21.

The second insert 120 may be directly connected to the other end of the connector 210 or may be indirectly connected to the other end of the connector 210 through the second adjuster.

The first insert 110 and the second insert 120 may be made of a non-metallic material. The first adjuster 230 and the connector 210 may be made of a metallic material.

In the measuring instruments of this embodiment, members directly in contact with the measuring instrument may be limited to the first insert 110 and the second insert 120. Thus, if only the first insert 110 and the second insert 120 are made of a non-metallic material, the measurement of the electromagnetic shielding effectiveness of the sample 90 may not be significantly affected.

The first adjuster 230 and the connector 210 connecting the first insert 110 and the second insert 120 may be made of a metallic material, and thus may have sufficient strength. Due to the first adjuster 230 and the connector 210 having sufficient strength, the coupling and alignment state between the first measuring instrument 10 and the second measuring instrument 20 may be maintained.

Although the embodiments of the present disclosure have been described above in the detail, the scope of rights of the present disclosure is not limited thereto, and various modifications and improvements made by those skilled in the art using the basic concept of the present disclosure defined in the following claims also fall within the scope of rights of the present disclosure.

What is claimed is:

1. An alignment device comprising:
an insert unit configured to be inserted, instead of a screw, into an alignment hole of a measuring instrument that is conventionally aligned using the screw; and
a support unit configured to support the insert unit on both sides of the alignment hole.

2. An alignment device comprising:
a first insert configured to be inserted into a first alignment hole, instead of a screw that penetrates a sample and is screwed into the first alignment hole of a first measuring instrument and a second alignment hole of a second measuring instrument, when the first measuring instrument and the second measuring instrument aligned with each other with the sample in between are provided;
a second insert configured to be inserted into the second alignment hole, instead of the screw;
a first adjuster connected to a second side of the first insert when a first side of the first insert is inserted into the first alignment hole; and
a connector extending along a path spaced apart from the first measuring instrument and the second measuring instrument,
wherein a first end of the connector is connected to the first adjuster whereas a second end of the connector is connected to the second insert, and
the first adjuster moves the first insert toward the first alignment hole or moves the first insert away from the first alignment hole.

3. The device of claim 2, wherein when the first alignment hole is made on a first surface of the first measuring instrument, a first plate is provided in face-to-face contact with the first surface, and
a first guide is provided that protrudes from the first plate toward the first alignment hole and is inserted into the first alignment hole,
wherein the first plate and the first guide are made of a non-metallic material, and
when the first guide is provided on a first side of the first plate, the first adjuster is connected to a second side of the first plate.

4. The device of claim 3, wherein when the second alignment hole is made on a second surface of the second measuring instrument, a second plate is provided in face-to-face contact with the second surface, and
a second guide is provided that protrudes from the second plate toward the second alignment hole and is inserted into the second alignment hole,
wherein the second plate and the second guide are made of a non-metallic material, and
when the second guide is provided on a first side of the second plate, the second end of the connector is connected to a second side of the second plate.

5. The device of claim 4, wherein the first guide protrudes from the first plate shorter than a depth of the first alignment hole, so that an end of the first guide inserted into the first alignment hole is not able to escape the first alignment hole and is located within the first alignment hole, and
the second guide protrudes from the second plate shorter than a depth of the second alignment hole, so that an end of the second guide inserted into the second alignment hole is not able to escape the second alignment hole and is located within the second alignment hole.

6. The device of claim 4, wherein a first support is provided to face the first surface at a position spaced apart from the first surface,
a second support is provided to face the second surface with the second plate interposed therebetween, and
a third support is provided to be spaced apart from the first measuring instrument and the second measuring instrument and to connect the first support and the second support,
wherein a first through hole is made in the first support through which the first adjuster is installed, and the first adjuster is screw-connected to the first through hole, and
when the first adjuster rotates in a forward direction, the first adjuster moves toward the first surface, bringing the first plate into close contact with the first surface and pushing the first guide into the first alignment hole, and
when the first adjuster rotates in a reverse direction, the first adjuster moves away from the first surface, separating the first plate from the first surface and separating the first guide from the first alignment hole.

7. The device of claim 6, wherein the first support, the second support, and the third support are made of a metallic material.

8. The device of claim 6, wherein the first support extends parallel to the first surface, the second support extends parallel to the second surface, and the third support extends at an angle to the first and second surfaces and connects the first support and the second support.

9. The device of claim 6, wherein a second through hole is formed in the second support through which the second adjuster is installed, and the second adjuster is screw-connected to the second through hole, and
when the second adjuster rotates in a forward direction, the second adjuster moves toward the second surface, bringing the second plate into close contact with the second surface and pushing the second guide into the second alignment hole, and
when the second adjuster rotates in a reverse direction, the second adjuster moves away from the second surface, separating the second plate from the second surface and separating the second guide from the second alignment hole.

10. The device of claim 6, wherein the first support extends on both sides from the first alignment hole along the first surface in a plan view over the first alignment hole, and
the second support extends on both sides from the second alignment hole along the second surface in a plan view over the second alignment hole.

11. The device of claim 2, wherein a first support is provided to face a first surface at a position spaced apart from the first surface of the first measuring instrument in which the first alignment hole is made,
a second support is provided to face a second surface of the second measuring instrument in which the second alignment hole is made, with the second plate interposed therebetween, and
a third support is provided to be spaced apart from the first measuring instrument and the second measuring instrument and to connect the first support and the second support,
wherein the third support may be expanded and contracted by the first adjuster.

12. The device of claim 11, wherein the third support is divided into two members movably connected to each other, wherein one member is provided with an elastic part extending toward the remaining one member, while the remaining one member has an insertion space into which the elastic part is inserted, and
the first adjuster is screw-connected to the third support to insert the elastic part into the insertion space or to pull the elastic part from the insertion space, depending on a rotation direction of the first adjuster.

13. The device of claim 2, wherein a first flange having the first alignment hole is provided at an end of the first measuring instrument, whereas a second flange having the second alignment hole is provided at an end of the second measuring instrument, and when the first flange and the second flange come into close contact with the sample in between, the connector is provided in a “U” shape in cross section with a groove formed in a center thereof,
the connector is arranged such that the first flange and the second flange, which are in close contact with each other, are inserted into the groove formed in the center of the connector, and
the connector is arranged to be spaced apart from the first measuring instrument and the second measuring instrument so as not to contact either the first flange or the second flange.

14. The device of claim 13, wherein the center of the connector faces side surfaces of the first flange and the second flange,
the first end of the connector extends toward an entrance of the first alignment hole exposed on the first surface of the first flange,
a first through hole through which the first adjuster is installed by screwing is formed at the first end of the connector,
the second end of the connector extends toward an entrance of the second alignment hole exposed on the second surface of the second flange, and
the second insert is directly connected to the second end of the connector or is indirectly connected to the second end of the connector through the second adjuster.

15. The device of claim 14, wherein the first insert and the second insert are made of a non-metallic material, whereas the first adjuster and the connector are made of a metallic material.
